(19) United States
(12) Patent Application Publication
(10) Pub. No.: US 2026/0176126 A1
(43) Pub. Date: Jun. 25, 2026

(54) OUT-OF-PLANE MICRO-ELECTROMECHANICAL DEVICE WITH REINFORCED STOPPER AND METHOD FOR MANUFACTURING A MICRO-ELECTROMECHANICAL DEVICE

(71) Applicant: STMicroelectronics International N.V., Geneva (CH)

(72) Inventors: Alessandro LUBERTO, Milano (IT); Gabriele GATTERE, Castronno (Varese) (IT)

(73) Assignee: STMicroelectronics International N.V., Geneva (CH)

(21) Appl. No.: 19/422,690

(22) Filed: Dec. 17, 2025

(30) Foreign Application Priority Data
Dec. 19, 2024 (IT) 102024000029109

(51) Int. Cl. B81B 3/00; B81C 1/00

(52) U.S. Cl. CPC B81B 3/001; B81C 1/00968; B81B 2207/115; B81C 2201/0105

(57) ABSTRACT

A micro-electromechanical device includes a support body and a movable mass. The movable mass is constrained to the support body and configured to oscillate with respect to the support body with an out-of-plane movement. The movable mass has a movable stopper covered by a protective coating on a side of the movable mass facing the substrate. The movable stopper with the protective coating is shaped so as to come into contact with a corresponding fixed stopper on the substrate when movement of the movable mass exceeds a working range.

### PRIORITY CLAIM

This application claims the priority benefit of Italian Application for Patent No. 10,202,4000029109 filed on Dec. 19, 2024, the content of which is hereby incorporated by reference in its entirety to the maximum extent allowable by law.

### TECHNICAL FIELD

The present invention relates to an out-of-plane micro-electromechanical device with reinforced stopper and to a method for manufacturing a micro-electromechanical device.

### BACKGROUND

As is known, many micro-electromechanical devices, especially inertial sensors, are provided with one or more masses movable with respect to a support body. The movements of the movable mass with respect to the support body, and in general the sensors as a whole, are defined as “in-plane” when the movable mass is constrained so as to translate parallel to a main face of the support body; and “out-of-plane” when the mass is constrained so as to oscillate around an axis parallel to the main face of the support body or translate perpendicular to the same main face.

To prevent accidental shocks of the movable mass against the support body, which might cause damage or stiction phenomena, it is common to provide stoppers that limit both the movement of the movable mass and the contact areas between the movable mass and the support body.

In “out-of-plane” inertial sensors, in particular, the movable mass is normally provided with stoppers on a surface arranged facing the main face of the support body. In general, stoppers of this type are formed by bumps of the movable mass that first come into contact with the support body in case of over-elongations. The movable mass and the stoppers are formed of the same semiconductor material, generally polycrystalline silicon.

However, stoppers may also be subject to wear or breakdowns due to shocks. In addition to losing their function of protecting the movable mass, in case of damage the stoppers may release dust or fragments that, depending on their size, may degrade the performance of the device or even compromise its operation.

The measures most frequently adopted to make the stoppers less vulnerable to failure concern the size and shape, but for several aspects the result obtainable is not always satisfactory.

Increasing the size, for example, in principle contributes to a better distribution of forces and pressures following a shock but may not be compatible with the general structure of the devices. In particular, the movable mass is normally traversed by a grid of channels perpendicular to the support body that serve, inter alia, during manufacturing for the evacuation of the sacrificial oxides when the movable structures are freed. The space available to anchor the stoppers between adjacent channels is limited and cannot be increased without redefining the design of the same channels, which may be very expensive and/or compromise other performance of the device.

The shape of the stoppers may be studied to avoid or reduce the concentration of force lines in proximity to edges. In practice, the stoppers are designed with rounded or, in any case, less pronounced edges. From the point of view of the manufacturing method, however, to form the stoppers it is necessary to use wet etches, that are less controllable than dry etches. More precisely, depressions of a shape complementary to the stoppers are formed in a sacrificial layer by a selective time etch. Subsequently, the movable mass is grown in an epitaxial reactor starting from a seed layer and, in the process, the material fills the cavities forming the stoppers. With a wet etch, the shape of the cavities is rounded and free of sharp edges, but it is difficult to control. Furthermore, the rounding of the shape inevitably reduces the contact surface with the support body, since the available space on the movable mass is limited due to the presence of the channels as discussed above.

In any case, the issue of the release of dust or fragments is only partially solved, because the stoppers may still be damaged.

There is accordingly a need in the art to provide a micro-electromechanical device and a method for manufacturing a micro-electromechanical device that allow the described limitations to be overcome or at least mitigated.

### SUMMARY

In an embodiment, a micro-electromechanical device comprises: a support body including a substrate; and a movable mass, constrained to the support body so as to be able to oscillate with respect to the support body with an out-of-plane movement; wherein the support body comprises a fixed stopper on the substrate and the movable mass comprises a movable stopper on a side of the movable mass facing the substrate in a position corresponding to the fixed stopper, the movable stopper being arranged and shaped so as to come into contact with the fixed stopper, when the movement of the movable mass exceeds a working range; and wherein the movable stopper comprises a protective coating.

In an embodiment, a method for manufacturing a micro-electromechanical device comprises: forming a support body including a substrate; forming a fixed stopper on the substrate; and forming a movable mass, constrained to the support body so as to be able to oscillate with respect to the support body with an out-of-plane movement. Forming the movable mass comprises: forming a movable stopper on a side of the movable mass facing the substrate in a position corresponding to the fixed stopper, the movable stopper being arranged and shaped so as to come into contact with the fixed stopper, when the movement of the movable mass exceeds a working range; and forming a protective coating covering the movable stopper.

### BRIEF DESCRIPTION OF THE DRAWINGS

For a better understanding of the present invention, preferred embodiments are presented, by way of non-limiting example, with reference to the attached drawings, wherein:

FIG. 1 is a cross-section through a micro-electromechanical device;

FIG. 2 is a top-plan view, with parts removed for clarity, of the micro-electromechanical device of FIG. 1;

FIG. 3 is a cross-section through a micro-electromechanical device; and

FIGS. 4-8 show cross-sections of a semiconductor wafer in subsequent processing steps of a method for manufacturing the micro-electromechanical device of FIG. 1.

### DETAILED DESCRIPTION

The following description refers to the arrangement shown in the drawings; consequently, expressions such as “above”, “below”, “upper”, “lower”, “top”, “bottom”, “right”, “left” and the like relate to the accompanying Figures and are not to be interpreted in a limiting manner.

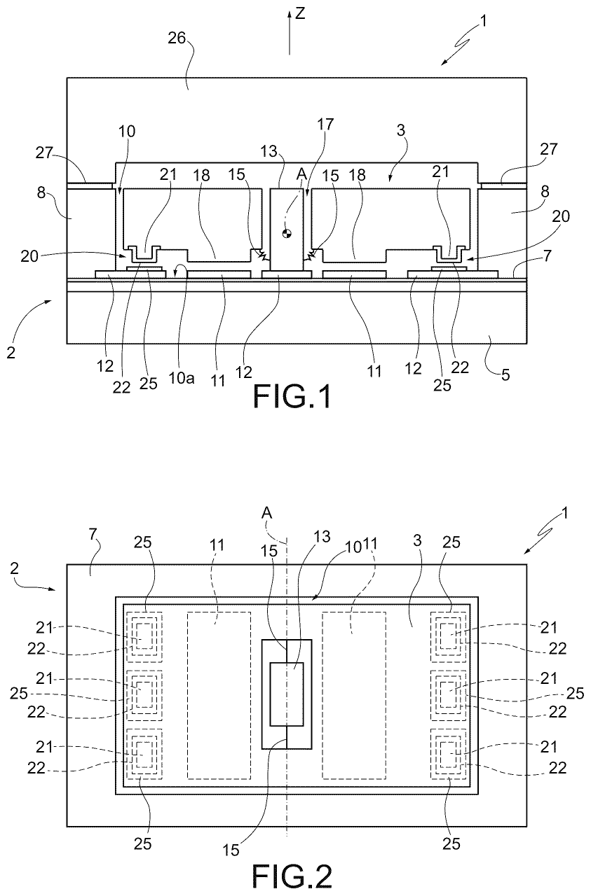

In FIGS. 1 and 2, a micro-electromechanical device of the out-of-plane type is illustrated and indicated as a whole by the numeral 1.

The micro-electromechanical device 1 comprises a support body 2, defined by a semiconductor chip having a substantially planar main face or front face, and a movable mass 3, elastically constrained to the support body 2 so as to be able to oscillate with respect to a balance position.

For the sake of simplicity, in the following reference will be made to the case in which the micro-electromechanical device 1 is an out-of-plane accelerometer or Z-accelerometer; however, it is understood that the invention is not limited to this type of devices and is applicable to all micro-electromechanical devices of the out-of-plane type.

It is also understood that in a micro-electromechanical device of the out-of-plane type the movable mass is constrained so as to carry out rotary and/or translational movements with a velocity component perpendicular to the main face of the support body.

In the case of the micro-electromechanical device 1 of FIGS. 1 and 2, in particular, the movable mass 3 oscillates with out-of-plane rotations around a non-barycentric axis A parallel to the main face of the support body 2 and perpendicular to a sensing direction Z. In the rest position, the movable mass 3 is parallel to the main face of the support body 2.

The support body 2 comprises a substrate 5, for example of monocrystalline silicon covered by a stack of a dielectric layer 6 (see FIG. 4) and a protective layer 7, and a frame 8 on the substrate 5. For example, the frame 8 may be of polycrystalline silicon. In the following, the stack of the dielectric layer 6 and the protective layer 7 are considered part of the substrate 5.

The support body 2 has a cavity 10, where the movable mass 3 is accommodated. In more detail, the cavity 10 is delimited laterally by the frame 8 and has a bottom wall 10a parallel to the main face of the support body 1.

Fixed sensing electrodes 11 and conductive tracks 12 are obtained from a polycrystalline silicon layer deposited over the stack of the protective dielectric layer 6 and protective layer 7.

An anchor 13 for the movable mass 3 is fixed to one of the conductive tracks 12, in a symmetrical position between the fixed sensing electrodes 11.

The movable mass 3 is supported by the anchor 13 by flexures 15, illustrated only schematically in FIGS. 1 and 2 and configured to allow the movable mass 3 to oscillate around the non-barycentric axis A, that is parallel to the main face of the support body 2. In the embodiment of FIGS. 1 and 2, in particular, the movable mass 3 has a quadrangular shape and has a central opening 17 that accommodates the anchor 13.

On a lower side 3a facing the substrate 5, the movable mass 3 has movable sensing electrodes 18, in positions corresponding to respective fixed sensing electrodes 11, and at least one movable stopper 20 (a plurality of movable stoppers 20 in the example of FIGS. 1 and 2). The movable stoppers 20 are formed and arranged so as to come into contact with a corresponding fixed stopper on the support body 2, when the rotation of the movable mass 3 exceeds a working range, avoiding direct shocks to the rest of the movable mass 3.

The movable stoppers 20 comprise respective teeth 21, protruding as a single piece from the movable mass 3 towards the substrate 5, and are provided with respective protective coatings 22 that cover the teeth 21.

The protective coatings 22 are made of a protective material having at least one parameter among elastic modulus, hardness and fracture toughness greater than the corresponding parameter of the material forming the movable mass 3 and the teeth 21, that in the case described is polycrystalline silicon. In one embodiment, moreover, the protective material is a semiconductor material.

A suitable and advantageously used protective material in the semiconductor sector is silicon carbide, that has all the parameters greater than the corresponding parameters of polycrystalline silicon, as is inferred from the following table:

| | Silicon | | Silicon carbide | |
|---|---|---|---|---|
| Elastic modulus | 160 | GPa | 400-450 | GPa |
| Hardness | 9630 | MPa | 23000-28500 | MPa |
| Fracture toughness | 1 | MPa m^{1/2} | 3.5-4.3 | MPa m^{1/2} |

Other non-limiting examples of materials that may be advantageously used for the protective coatings 22 include, inter alia, silicon nitride and aluminum oxide.

In the embodiment of FIGS. 1 and 2, the micro-electromechanical device 1 also comprises stop pads 25, formed on respective conductive tracks 12 on the bottom wall 10a of the cavity 10 in positions corresponding to respective movable stoppers 20. The stop pads 25 define the fixed stoppers on the substrate 5. In this manner, in case of stresses that bring the movable mass 3 into contact with the support body 2, the movable stoppers 20 hit the respective stop pads 25, while the conductive tracks 12 remain unharmed.

The stop pads 25 are made of the same material as the movable stoppers 20, here silicon carbide.

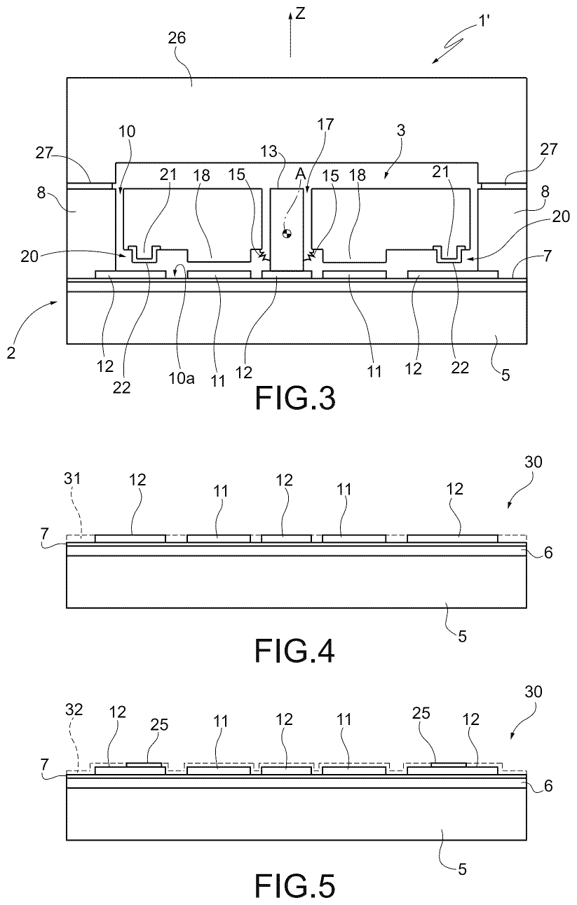

The stop pads 25 may, however, not be present, according to design preferences, as in the micro-electromechanical device 1′ of FIG. 3; in this case, the fixed stoppers on the substrate 5 are defined by portions of the conductive tracks 12 (as in the case of FIG. 3) or, possibly, of the protective layer 7 (not shown). The regions most exposed to risks of breakdown are in fact the movable stoppers 20, that are however provided with the protective coatings 22 and may be sufficiently resistant to damage and wear also based on the type of use envisaged for the micro-electromechanical device 1′.

The micro-electromechanical device 1 further comprises a cap 26, that is bonded to the frame 8 of the support body 2 by a stiction layer 27 and seals the cavity 10 in which the movable mass 3 is accommodated.

The protective coatings 22 offer sufficient mechanical strength to substantially reduce the risk of damage from severe shocks and wear of the stoppers 21 of the movable mass 3. The micro-electromechanical device 1 (and 1′) is less exposed to performance degradation, malfunctions and irreversible failures due to the fact that the detachment of dusts and fragments from the movable mass 3 is eliminated or at least significantly reduced.

The stop pads 25 offer a corresponding protection to the parts of the support body 2 of the micro-electromechanical device 1 exposed to shocks, in particular to the conductive tracks 12. The stop pads 25 therefore also contribute to reducing the risk of damage and increasing the resistance to wear.

The use of a semiconductor material for the protective coatings and the stop pads avoids the trapping of charges that might interfere with the capacitive reading of the position of the movable mass and alter the performance of the micro-electromechanical device.

The presence of protective material is advantageously limited to the movable stopper 20 and the stop pad 25, if present. The risk is thus reduced that the micro-electromechanical device 1, 1′ deforms during manufacturing, for example due to differences in the coefficient of thermal expansion between the material forming the movable stopper 20 and the stop pad 25 and the materials forming the substrate 5-7, the conductive tracks 12 and the movable mass 3.

A method for manufacturing the micro-electromechanical device 1 will be described below with reference to FIGS. 4-8.

Initially (as shown in FIG. 4), on a semiconductor wafer 30 comprising the substrate 5, there are formed the dielectric layer 6, for example by thermal oxidation, and the protective layer 7, that is made of a material resistant and impermeable to the hydrofluoric acid used in the subsequent processing steps.

A polycrystalline silicon semiconductor layer 31 is then deposited and patterned by a photolithographic process to form the fixed sensing electrodes 11 and the conductive tracks 12, as shown in FIG. 5.

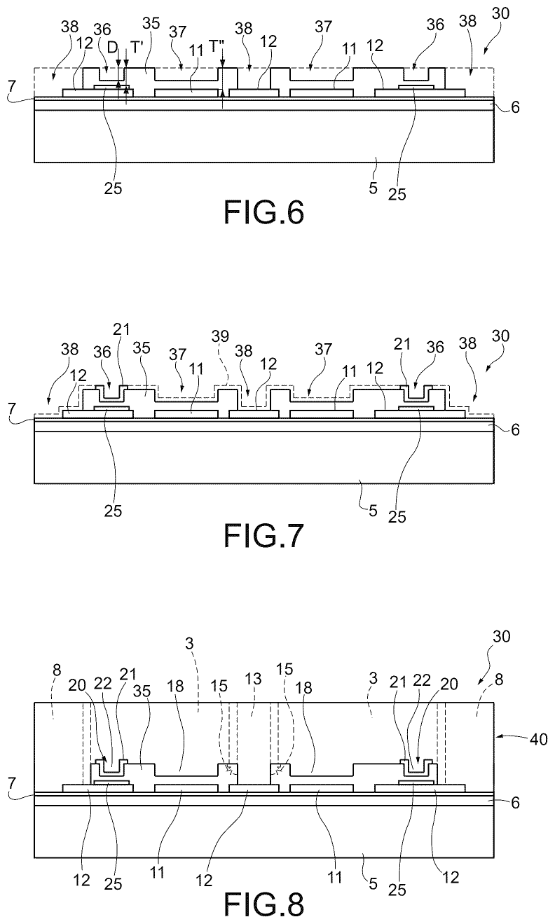

Then (as shown in FIG. 6), a coating layer 32, here of silicon carbide, is deposited conformally on the wafer 30, covering the fixed sensing electrodes 11, the conductive tracks 12 and the substrate 5, in particular the protective layer 7. The stop pad layer 32 is patterned by a masked etch and selectively removed to form the stop pads 25 on respective conductive tracks 12. In one embodiment, outside the stop pads 25 the stop pad layer 32 is completely removed.

A sacrificial layer 35 is subsequently deposited on the wafer 30 and is patterned in two steps to form stopper recesses 36, electrode recesses 37 and through recesses 38 in positions where the movable stoppers 20, the movable sensing electrodes 18 and the structures fixed to the substrate 5, which include the frame 8 and the anchor 13 of the movable mass 2, respectively, will subsequently be formed. In particular, the stopper recesses 36 are formed in positions corresponding to respective stop pads 25 and the electrode recesses 37 are formed in positions corresponding to respective fixed sensing electrodes 11. In a first step, the stopper recesses 36 and the electrode recesses 37 are formed by a time etch, for example a dry etch. The stopper recesses 36 and the electrode recesses 37 extend in the sacrificial layer 35 to an etch depth D lower than thicknesses T′, T″ of the sacrificial layer 35 in respective corresponding positions. In a second step, the stopper recesses 36 and the electrode recesses 37 are protected and the through recesses 38 are opened throughout the entire thickness of the sacrificial layer 35, uncovering respective underlying portions of the conductive tracks 12 and of the substrate 5 (more precisely, of the protective layer 7 covering the substrate 5 and the dielectric layer 6). It is understood that the step of forming the stopper recesses 36 and the electrode recesses 37 and the step of forming the through recesses 38 may be performed either in the order described above or in the reverse order.

As shown in FIG. 7, a coating layer 39, here of silicon carbide, is deposited conformally on the entire wafer 30 and, in particular, covers the inside of the recesses 36, 37, 38. The coating layer 39 is patterned by a further masked etch and selectively removed outside the stopper recesses 36, in particular in the electrode recesses 37 and in the through recesses 38. It is understood instead that residual portions of the coating layer 39 may remain along the margins of the stopper recesses 36. In this manner, the masked etch of the coating layer 39 patterns the protective coatings 22.

After depositing a semiconductor seed layer (not shown in detail), a structural layer 40 is formed by an epitaxial reactor growth (FIG. 8), to a desired thickness for the movable mass 3 and the frame 8, in accordance with design preferences. In the embodiment described herein, the semiconductor material forming the structural layer is polycrystalline silicon. The structural layer 40 fills the stopper recesses 36, the electrode recesses 37 and the through recesses 38 forming the teeth 21 in the stopper recesses 36, the movable sensing electrodes 18 in the electrode recesses 37 and the frame 8 and the anchor 13 of the movable mass 3 in the through recesses 38, respectively. In forming the teeth 21, the structural layer 40 adheres to the protective coatings 22 and the stoppers 20 are thus defined.

After the epitaxial reactor growth, the structural layer 40 is patterned with a lithographic process to form the frame 8 of the support body 2, the movable mass 3, the anchor 13 and the flexures 15 (as shown in FIGS. 1 and 2). Subsequently, the sacrificial layer 35 is etched, for example in a hydrofluoric acid bath, and completely removed, freeing the movable mass 3 (as shown in FIGS. 1 and 2). Finally, a cap wafer (not shown here) is bonded to the wafer 30 to form a composite wafer, which is diced and divided into dice, each of which comprises an instance of the micro-electromechanical device 1 of FIG. 1.

Essentially the same process may also be used to manufacture the micro-electromechanical device 1′ of FIG. 3. In this case, the deposition and patterning steps of the stop pad layer 32 are obviously not performed, since in the micro-electromechanical device 1′ the stop pads are not present.

Finally, it is evident that modifications and variations may be made to the micro-electromechanical device and to the method described, without departing from the scope of the present invention, as defined in the attached claims.

In particular, it is understood that the number, shape and arrangement of the stoppers and possibly of the stop pads may be chosen in accordance with design preferences. For example, stoppers and stop pads may be formed on only one side of the movable mass if the risk of harmful shocks on the opposite side is sufficiently low. In accordance with design preferences, even a single movable stopper might be present, with or without a stop pad on the substrate.

1. A micro-electromechanical device, comprising:
a support body including a substrate;
wherein the support body comprises a first stopper on the substrate; and
a movable mass constrained to the support body and configured to be able to oscillate with respect to the support body with an out-of-plane movement;
wherein the movable mass comprises a second stopper on a side of the movable mass facing the substrate in a position corresponding to the first stopper;
a protective coating covering the second stopper; and
wherein the second stopper covered by the protective coating is arranged and shaped so as to come into contact with the first stopper when movement of the movable mass exceeds a working range.

2. The device according to claim 1, wherein the movable mass and the second stopper are made of a first material and the protective coating of the second stopper is made of a second material having at least one parameter among elastic modulus, hardness and fracture toughness greater than a corresponding parameter of the first material.

3. The device according to claim 2, wherein the first material is polycrystalline silicon and the second material is a material selected from the group consisting of: silicon carbide, silicon nitride and aluminum oxide.

4. The device according to claim 3, wherein the second material is a semiconductor material.

5. The device according to claim 1, wherein the second stopper comprises a tooth, protruding as a single piece from the movable mass towards the substrate from the side of the movable mass facing the substrate, and wherein the tooth is covered by the protective coating.

6. The device according to claim 1, wherein the first stopper comprises a stop pad, formed on the substrate in a position corresponding to the second stopper.

7. The device according to claim 6, wherein the second stopper and the first stopper are made of a same material.

8. A method for manufacturing a micro-electromechanical device, comprising:
forming a support body including a substrate;
forming a first stopper on the substrate; and
forming a movable mass constrained to the support body and configured to be able to oscillate with respect to the support body with an out-of-plane movement;
wherein forming the movable mass comprises:
forming a second stopper on a side of the movable mass facing the substrate in a position corresponding to the first stopper;
forming a protective coating covering the second stopper; and
wherein the second stopper covered by the protective coating is arranged and shaped so as to come into contact with the first stopper when movement of the movable mass exceeds a working range.

9. The method according to claim 8, wherein forming the movable mass comprises:
forming a sacrificial layer on a semiconductor wafer including the substrate;
forming first through recesses in the sacrificial layer;
forming, on the sacrificial layer, a semiconductor structural layer connected to the substrate through the first recesses;
patterning the movable mass in the structural layer; and
removing the sacrificial layer to free the movable mass.

10. The method according to claim 9, wherein forming the protective coating comprises:
forming second recesses in the sacrificial layer to an etch depth lower than a thickness of the sacrificial layer in a position corresponding to the second recesses;
depositing a first coating layer on the wafer so as to cover the second recesses internally; and
removing the first coating layer selectively outside the second recesses.

11. The method according to claim 10, wherein forming the second stopper comprises filling the second recesses with portions of the structural layer.

12. The method according to claim 9, wherein forming the structural layer comprises performing an epitaxial reactor growth.

13. The method according to claim 9, further comprising, before forming the sacrificial layer:
forming a second coating layer, made of a same material as the first coating layer, on the substrate; and
forming the first stopper from the second coating layer.

14. The method according to claim 8, wherein the movable mass and second stopper are made of a first material and the first coating layer is made of a second material having at least one parameter among elastic modulus, hardness and fracture toughness greater than a corresponding parameter of the first material.

15. The method according to claim 14, wherein the first material is polycrystalline silicon and the second material is a material selected from the group consisting of: silicon carbide, silicon nitride and aluminum oxide.

16. The method according to claim 15, wherein the second material is a semiconductor material.
